(19) United States
(12) Patent Application Publication
(10) Pub. No.: US 2010/0241916 A1
(43) Pub. Date: Sep. 23, 2010

(54) SCAN TEST CIRCUIT AND METHOD FOR CHANGING CIRCUIT TO SCAN TEST CIRCUIT

(75) Inventors: Yusuke Takahashi, Kamakura-shi (JP); Michito Nakanishi, Kawasaki-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, TOKYO (JP)

(21) Appl. No.: 12/726,470

(22) Filed: Mar. 18, 2010

(30) Foreign Application Priority Data
Mar. 23, 2009 (JP) 2009-69648

(51) Int. Cl. G01R 31/3177; G06F 11/25

(52) U.S. Cl. 714/731; 714/E11.155; 714/726

(57) ABSTRACT

A scan test circuit that performs a normal operation, a shift operation, and a capture operation based on a control signal includes: plural combination circuits; plural scan flip-flops, the plural scan flip-flops and the plural combination circuits being alternately connected in series; a flip-flop connected between the scan flip-flop and the subsequent combination circuit not through the combination circuit; and a selector switched between a first mode and a second mode by a switching signal, the selector feeding observation data of a predetermined observation target circuit into the flip-flop in the first mode, the selector feeding output data of a preceding circuit of the flip-flop into the flip-flop in the second mode, the selector being able to be switched to the first mode during the capture operation in a scan test, the selector being able to be switched to the second mode during the normal operation and the shift operation in the scan test.

### CROSS REFERENCE TO RELATED APPLICATIONS

This application is based upon and claims the benefit of priority from the prior Japanese Patent Application No. 2009-69648 filed on Mar. 23, 2009 in Japan, the entire contents of which are incorporated herein by reference.

### BACKGROUND OF THE INVENTION

1. Field of the Invention

The present invention relates to a scan test circuit and a method for changing a circuit to a scan test circuit.

2. Related Art

Currently, a scan test is performed as one of tests of Large Scale Integration (hereinafter abbreviated as LSI). The scan test is performed as follows using the scan test circuit in which a test circuit is incorporated into LSI. That is, internal data that is set to each combination circuit of LSI is fed in time series from an external input terminal, and data that is output from each combination circuit according to fed data is output in time series from an external output terminal of LSI and compared to an expected value. Accordingly, quality of each combination circuit can efficiently be tested.

Generally, a complicated combination circuit and a simple combination circuit are mixed in LSI. In order to enhance a fault coverage of the complicated combination circuit, it is necessary that combinations of plural pieces of data simultaneously fed into the complicated combination circuit be sequentially changed to compare the expected value and the output data corresponding to the input data of each combination. Therefore, it is necessary that a string of capture operations and shift operations is iterated many times equivalent to the number of combinations of pieces of data fed into the complicated combination circuit, and a long test time is required. As a result, the test time of the complicated combination circuit has a large influence on the test time of the whole of LSI.

When observability of the complicated combination circuit is enhanced, the test time can be shortened while the fault coverage is maintained. The enhancement of the observability means that the data that cannot be observed from the outside of LSI can be observed.

On the other hand, the combination circuit that is not incorporated in the scan test circuit is incorporated in the scan test circuit to enhance the observability, which allows the fault coverage of LSI to be enhanced.

However, in order to enhance the observability, it is necessary that the data be able to be observed by adding a flip-flop dedicated to the scan test, which increases an area.

For example, a circuit disclosed in Japanese Patent Application Laid-Open No. 2004-279266 is known as the scan test circuit.

### SUMMARY OF THE INVENTION

In accordance with one embodiment of the present invention, there is provided a scan test circuit that performs a normal operation, a shift operation, and a capture operation based on a control signal, the scan test circuit including: a plurality of combination circuits; a plurality of scan flip-flops, the plurality of scan flip-flops and the plurality of combination circuits being alternately connected in series; a flip-flop connected between the scan flip-flop and the subsequent combination circuit not through the combination circuit; and a selector switched between a first mode and a second mode by a switching signal, the selector feeding observation data of a predetermined observation target circuit into the flip-flop in the first mode, the selector feeding output data of a preceding circuit of the flip-flop into the flip-flop in the second mode, the selector being able to be switched to the first mode during the capture operation in a scan test, the selector being able to be switched to the second mode during the normal operation and the shift operation in the scan test.

Moreover, in accordance with another embodiment of the present invention, there is provided a method for changing a predetermined circuit to a scan test circuit, the predetermined circuit comprising a plurality of combination circuits, a plurality of first flip-flops, the plurality of first flip-flops and the plurality of combination circuits being alternately connected in series, and a second flip-flop connected between the first flip-flop and the subsequent combination circuit not through the combination circuit, the method including: replacing the plurality of first flip-flops with a plurality of scan flip-flops, respectively; after replacing, changing wiring such that a scan test is able to be performed; and after changing the wiring, connecting a selector switched between a first mode and a second mode by a switching signal such that observation data of a predetermined observation target circuit is fed into the second flip-flop in the first mode, and such that output data of a preceding circuit of the second flip-flop is fed into the second flip-flop in the second mode, the selector being able to be switched to the first mode during a capture operation in the scan test, the selector being able to be switched to the second mode during a normal operation and a shift operation in the scan test.

In addition, in accordance with a further embodiment of the present invention, there is provided a method for changing a predetermined circuit to a scan test circuit, the predetermined circuit comprising a plurality of combination circuits, a plurality of first flip-flops, the plurality of first flip-flops and the plurality of combination circuits being alternately connected in series, and a second flip-flop connected between the first flip-flop and the subsequent combination circuit not through the combination circuit, the method comprising: replacing the plurality of first flip-flops with a plurality of scan flip-flops, respectively; replacing the second flip-flop with a second scan flip-flop; after replacing, providing wiring such that the second scan flip-flop acts as a flip-flop; after providing the wiring, changing the wiring such that a scan test is able to be performed; and after changing the wiring, connecting a selector switched between a first mode and a second mode by a switching signal such that observation data of a predetermined observation target circuit is fed into the second scan flip-flop in the first mode, and such that output data of a preceding circuit of the second scan flip-flop is fed into the second scan flip-flop in the second mode, the selector being able to be switched to the first mode during a capture operation in the scan test, the selector being able to be switched to the second mode during a normal operation and a shift operation in the scan test.

### BRIEF DESCRIPTION OF THE DRAWINGS

FIG. 1 is a circuit diagram illustrating a circuit in which synchronous design is made on the premise of the scan test;

FIG. 2 is a circuit diagram of a scan test circuit according to a first comparative example;

FIG. 3 is a circuit diagram of a scan test circuit according to a second comparative example;

FIG. 4 is a circuit diagram of a scan test circuit according to a first embodiment of the invention;

FIG. 4A is a flowchart illustrating a method for changing a circuit to the scan test circuit according to the first embodiment of the invention;

FIG. 5 is a circuit diagram of a scan test circuit according to a second embodiment of the invention; and

FIG. 6 is a circuit diagram of a scan test circuit according to a third embodiment of the invention.

### DETAILED DESCRIPTION OF THE INVENTION

Before describing embodiments of the invention, a scan test circuit the inventors perceive will be described.

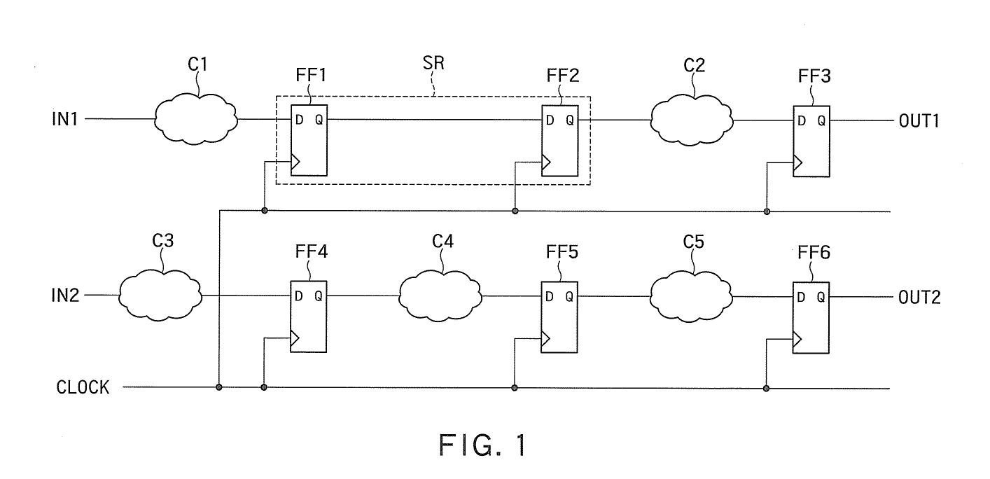

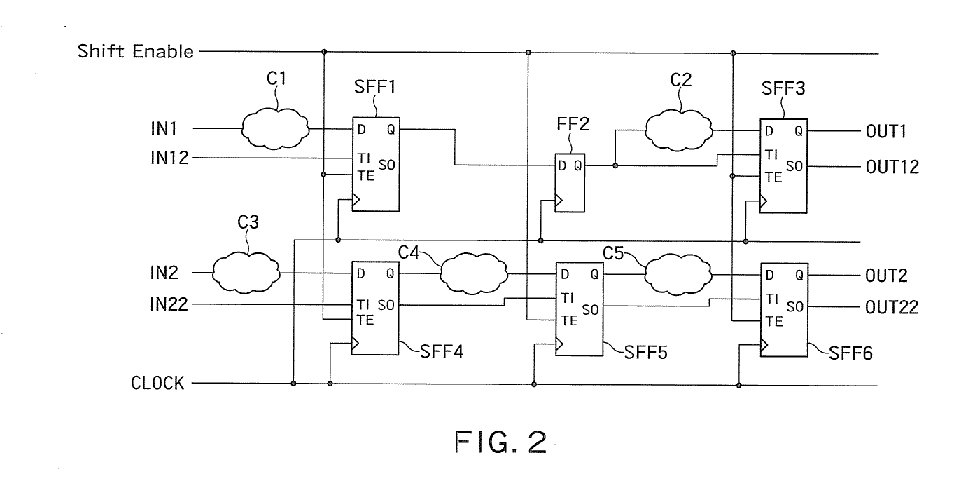

Generally, a circuit designed so as to have a predetermined function is modified so as to deal with the scan test using a design tool, thereby obtaining the scan test circuit. This point will be described with reference to FIGS. 1 and 2.

FIG. 1 is a circuit diagram illustrating a circuit in which synchronous design is made on the premise of the scan test. In the circuit, flip-flops are connected in series and a combination circuit is inserted and connected between the flip-flops or the flip-flop and an external input/output terminal (not illustrated). FIG. 1 illustrates part of the circuit.

Specifically, data IN1 is fed into a combination circuit C1 from a preceding flip-flop (not illustrated). The output data of the combination circuit C1 is fed into a D terminal of a flip-flop FF1. The output data of the flip-flop FF1 is fed into a D terminal of a flip-flop FF2. The output data of the flip-flop FF2 is fed into a D terminal of a combination circuit C2. The output data of the combination circuit C2 is fed into a D terminal of a flip-flop FF3. Output data OUT1 of the flip-flop FF3 is fed into a subsequent flip-flop or combination circuit (not illustrated).

Data IN2 is fed into a combination circuit C3 from a preceding flip-flop (not illustrated). The output data of the combination circuit C3 is fed into a D terminal of a flip-flop FF4. The output data of the flip-flop FF4 is fed into a complicated combination circuit C4. The output data of the complicated combination circuit C4 is fed into a D terminal of a flip-flop FF5. The output data of a flip-flop FF5 is fed into a combination circuit C5. The output data of the combination circuit C5 is fed into a D terminal of a flip-flop FF6. Output data OUT2 of the flip-flop FF6 is fed into a subsequent flip-flop or combination circuit (not illustrated).

A clock signal is fed into each of the flip-flops FF1 to FF6. The flip-flops FF1 and FF2 constitute a shift register SR. The shift register SR does not include the combination circuit between the flip-flops FF1 and FF2.

An example in which the circuit of FIG. 1 is modified to deal with the scan test using the design tool will be described below.

FIG. 2 is a circuit diagram of a scan test circuit according to a first comparative example. Each of the flip-flops FF1 and FF3 to FF6 in the circuit of FIG. 1 is changed to scan flip-flops SFF1 and SFF3 to SFF6. The flip-flop FF2 is not changed. Terminals TE of the scan flip-flops SFF1 and SFF3 to SFF6 are connected to one another, and a shift enable signal (Shift Enable: control signal) is fed into the terminals TE. Data IN12 is fed into an input terminal TI of the scan flip-flop SFF1 from the preceding scan flip-flop (not illustrated). In the scan flip-flop SFF3, an input terminal TI is connected to an output terminal Q of the preceding flip-flop FF2, and data OUT12 is fed from an output terminal SO into a subsequent circuit (not illustrated). Data IN22 is fed from a preceding scan flip-flop (not illustrated) into an input terminal TI of the scan flip-flop SFF4. In the scan flip-flop SFF5, an input terminal TI is connected to an output terminal SO of the preceding scan flip-flop SFF4. In the scan flip-flop SFF6, an input terminal TI is connected to an output terminal SO of the preceding scan flip-flop SFF5, and data OUT22 is fed from the output terminal SO into a subsequent circuit (not illustrated). FIG. 2 illustrates two scan chains having the above-described configurations. Because other circuit configurations are identical to those of the circuit of FIG. 1, the same component is designated by the same numeral, and the description will not be repeated.

That is, the scan test circuit includes scan flip-flops SFF1 and SFF3 that are connected in series through the combination circuits C1 and C2, and the flip-flop FF2 that is inserted and connected between the scan flip-flop SFF1 and the subsequent combination circuit C2 not through the combination circuits C1 and C2.

Generally, the complicated combination circuit C4 includes plural input terminals and plural output terminals, and the scan test is performed while combinations of pieces of data fed into the plural input terminals are sequentially changed. However, only one input terminal and one output terminal are illustrated in FIG. 2 for clarifying explanation.

For the low shift enable signal, the scan flip-flops SFF1 and SFF3 to SFF6 store the data at the input terminal D and output the stored data from the output terminals Q and SO according to the clock. For the high shift enable signal, the scan flip-flop SFF1 and SFF3 to SFF6 store the data at the input terminal TI and output the stored data from the output terminals Q and SO according to the clock.

That is, during a normal operation, the shift enable signal is set low and the scan test circuit operates equivalent to the circuit of FIG. 1. During the scan test, the shift enable signal is set low and the scan test circuit performs a capture operation, and the shift enable signal is set high and the scan test circuit performs a shift operation.

In the capture operation, as with the normal operation, the scan flip-flops SFF1 and SFF3 to SFF6 store the pieces of output data of the preceding combination circuits C1 to C5 and output the stored data according to the clock. In the shift operation, the scan flip-flops SFF1 and SFF3 to SFF6 store the pieces of output data of the preceding scan flip-flops SFF1, SFF4, and SFF5 or the output data of the flip-flop FF2 and output the stored data according to the clock. The shift operation is repeated, and the pieces of data stored during the capture operation are sequentially shifted to take out the pieces of data from the external output terminal. In order to take out all the pieces of data from the external output terminal, it is necessary to feed the number of clocks equivalent to the number of stages of the flip-flops in the scan chain. Therefore, a longer time is required for the shift operation than that of the capture operation.

When the shift register SR, that does not include the combination circuit, exists between the flip-flops FF1 and FF2 as illustrated in FIG. 1, the subsequent flip-flop FF2 in the shift register SR is not changed to the scan flip-flop in the changing processing performed by the design tool. Alternatively, after the flip-flop FF2 is changed to the scan flip-flop, the scan flip-flop is changed to the flip-flop FF2 again.

This is attributed to the following fact. Because the flip-flop FF2 stores the same data (output data, of the scan flip-flop SFF1) in the capture operation and the shift operation, it is not necessary to use the scan flip-flop whose area is larger than that of the flip-flop.

Specifically, the data stored during the capture operation by the flip-flop FF2 does not reflect the state of the combination circuit unlike other scan flip-flops SFF1 and SFF3 to SFF6. Therefore, the flip-flop FF2 is not effectively utilized in the test of the combination circuit. Generally, because the scan test circuit includes plural shift registers, the plural flip-flops constituting the shift registers are not effectively utilized.

On the other hand, occasionally a design tool that has a function different from that of above description to change all the flip-flops to the scan flip-flops is used in order to change the circuit to the scan test circuit.

An example in which the circuit of FIG. 1 is modified to deal with the scan test using the above design tool will be described below.

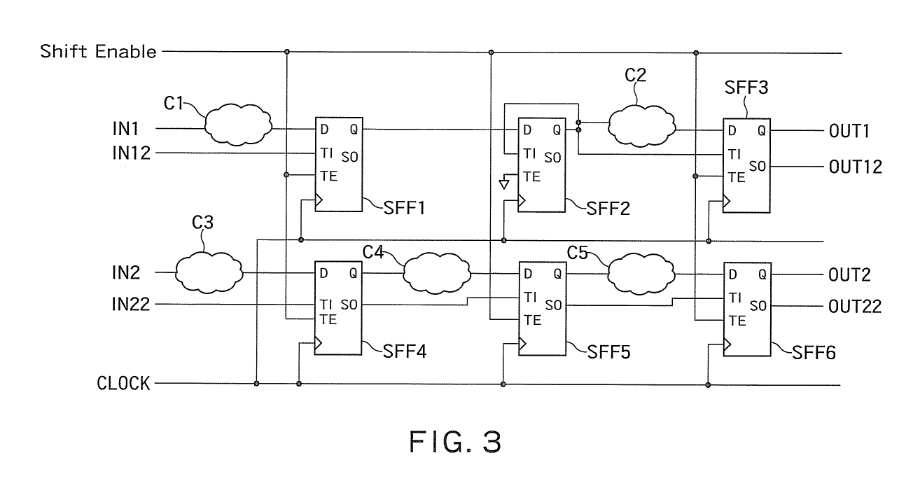

FIG. 3 is a circuit diagram of a scan test circuit according to a second comparative example. In FIG. 3, the same component as the scan test circuit of the first comparative example of FIG. 2 is designated by the same numeral, and the description will not be repeated.

As illustrated in FIG. 3, the subsequent flip-flop FF2 constituting the shift register SR of FIG. 1 is changed to a scan flip-flop SFF2. In the scan flip-flop SFF2, a terminal TE is grounded, and an input terminal TI is connected to an output terminal Q, whereby the scan flip-flop SFF2 is operated like the flip-flop FF2. That is, the scan test circuit is operated like the circuit of FIG. 2.

Embodiments of the invention will be described with reference to the drawings. However, the embodiments will not limit the invention.

### First Embodiment

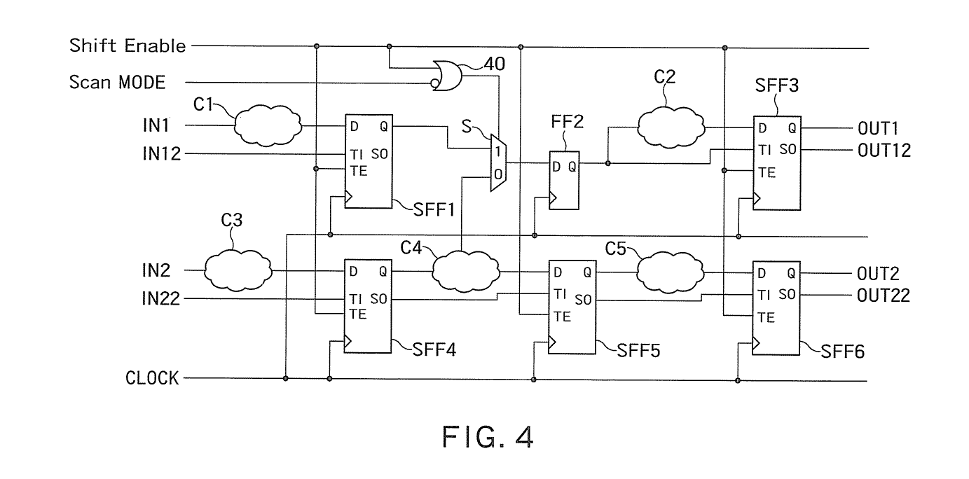

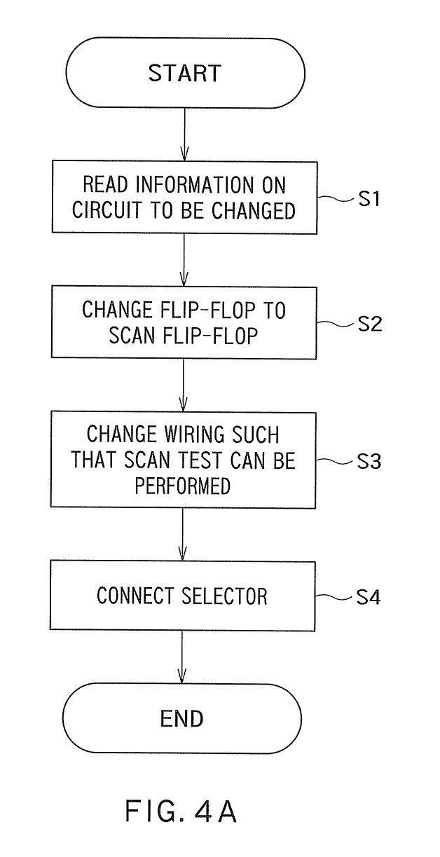

A first embodiment of the invention will be described with reference to FIG. 4. One of characteristics of the first embodiment is that the internal data of the combination circuit that functions as the observation target circuit is stored in the subsequent flip-flop of the shift register in the scan chain during the capture operation.

FIG. 4 is a circuit diagram of a scan test circuit of the first embodiment. The circuit of FIG. 4 includes the following configuration in addition to the circuit of FIG. 2. In a selector S, one input terminal “0” is connected to a midpoint of the complicated combination circuit C4, the other input terminal “1” is connected to the output terminal Q of the scan flip-flop SFF1, and an output terminal is connected to the input terminal D of the flip-flop FF2. In an OR circuit 40, the shift enable signal is fed into one input terminal, a scan mode signal (Scan MODE) is fed into the other inverted input terminal, and the output terminal is connected to a control terminal of the selector S to output a switching signal. Because other circuit configurations are identical to those of the scan test circuit of FIG. 2, the same component is designated by the same numeral, and the description will not be repeated.

The scan mode signal is set high during the scan test, and is set low except for the scan test (that is, during the normal operation and the test except for the scan test).

When the scan mode signal is set low (in the normal operation), the selector S outputs the data at the input terminal “1” to the flip-flop FF2 independently of the shift enable signal (second mode).

When the scan mode signal is set high and the shift enable signal is set low (in the capture operation), the selector S outputs the data of the input terminal “0” to the flip-flop FF2 (first mode).

When the scan mode signal is set high and the shift enable signal is set high (in the shift operation), the selector S outputs the data of the input terminal “1” to the flip-flop FF2 (second mode).

Therefore, during the capture operation, the subsequent flip-flop FF2 in the shift register SR stores the data (observation data) at the midpoint of the complicated combination circuit C4 (observation target circuit) according to the clock. That is, the position in which the flip-flop FF2 makes the observation in the capture operation is changed using the selector S, and the data at the midpoint of the complicated combination circuit C4 can be observed.

In the normal operation and the shift operation, because the flip-flop FF2 stores the output data of the scan flip-flop SFF1 that is the preceding circuit thereof, the scan test circuit operates like the circuit of FIG. 2.

As described above, according to the first embodiment, during the capture operation, the internal data of the complicated combination circuit C4 is stored in the subsequent flip-flop FF2 whose input terminal is not connected to the combination circuit, in the shift register SR, so that the internal data can be observed by the scan test. That is, the observability can be enhanced. Therefore, the number of combinations of the pieces of data fed into the combination circuit C4 decreases while the fault coverage equal to that of the circuit of FIG. 2 is maintained. Therefore, the number of capture operations and the number of shift operations occupying most of the test time can decrease to shorten the test time.

Because the flip-flop FF2 that is not effectively utilized in the test of the combination circuit is used to observe the internal data, it is not necessary to newly add the flip-flop dedicated to the scan test in order to observe the internal data. Therefore, the increase in area is prevented.

In addition, the selector S can be disposed using the design tool when the scan chain of FIG. 2 is formed. For example, using the design tool, the combination circuit C4 having the longest delay time in LSI is searched, any node is specified in the combination circuit C4, and the node may be connected to the input terminal “0” of the selector S.

A method for changing the circuit to the scan test circuit of FIG. 4 using the design tool will be described with reference to FIG. 4A.

FIG. 4A is a flowchart illustrating a method for changing a circuit to the scan test circuit of the first embodiment.

First, information on the circuit that is changed to the scan test circuit is read using the design tool (Step S1). For example, information on the circuit of FIG. 1 is read. The following pieces of processing are performed using the design tool.

Then the predetermined flip-flop of the read circuit is changed to the scan flip-flop (Step S2). For example, as described above, the flip-flops FF1 and FF3 to FF6 are changed.

Then wiring is changed to form the scan chain such that the scan test can be performed (Step S3). Therefore, the scan test circuit of FIG. 2 is obtained.

Then the selector S is connected (Step S4). Specifically, as illustrated in FIG. 4, the input terminal “1” of the selector S is connected to the output terminal Q of the scan flip-flop SFF1, and the output terminal of the selector S is connected to the input terminal D of the flip-flop FF2. The midpoint of the combination circuit C4 is connected to the input terminal “0” of the selector S. For example, as described above, the combination circuit C4 having the longest delay time in LSI is searched, any node is specified in the combination circuit C4, and the node may be connected to the selector S. As described above, the control terminal of the selector S is connected to the OR circuit 40, thereby obtaining the scan test circuit of FIG. 4.

### Modification of First Embodiment

A modification of the first embodiment will be described below. In the modification, an observation target selection signal is fed into the OR circuit 40 instead of the scan mode signal.

Generally, a stuck-at fault test and a delay fault test are performed as the scan test. In the stuck-at fault test, logic between the flip-flops and logic between the flip-flop and the external terminal are tested. In the delay fault test, a signal transmission time between the flip-flops is tested. In the delay fault test, it is necessary to perform the test in the same signal pathway as the normal operation.

According to the modification, even if the scan test is performed (scan mode signal is set high), whether the observation data of the complicated combination circuit C4 is stored during the capture operation can be switched by setting the observation target selection signal. Therefore, when the delay fault test is performed as the scan test, the observation data of the complicated combination circuit C4 is not stored during the capture operation, but the output data of the scan flip-flop SFF1 can be stored like the normal operation. On the other hand, when the stuck-at fault test is performed as the scan test, the observation data of the complicated combination circuit C4 is stored during the capture operation, and the effect similar to that of the first embodiment is obtained.

### Second Embodiment

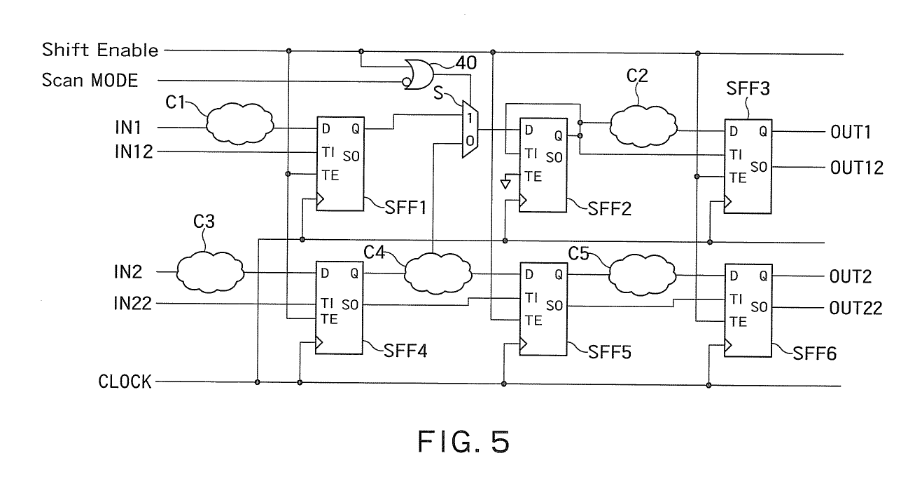

A second embodiment of the invention will be described with reference to FIG. 5. The second embodiment relates to a scan test circuit obtained using a design tool that changes all the flip-flops to the scan flip-flops. That is, the second embodiment differs from the first embodiment in that the subsequent flip-flop in the shift register is the scan flip-flop.

FIG. 5 is a circuit diagram of a scan test circuit of the second embodiment. The circuit includes a scan flip-flop SFF2 that acts as the flip-flop instead of the flip-flop FF2 in the scan test circuit of FIG. 4. Because other circuit configurations are identical to those of the scan test circuit of FIG. 4, the same component is designated by the same numeral, and the description will not be repeated.

According to the second embodiment, even if the design tool that changes all the flip-flops to the scan flip-flops is used, the selector S is used to select the data fed into the scan flip-flop SFF2, thereby obtaining the effect similar to that of the first embodiment. That is, the observability can be enhanced to shorten the test time independently of the function of the design tool.

In addition, the method for changing the circuit to the scan test circuit of FIG. 5 differs from that of the first embodiment in the following point. That is, in Step S2 of FIG. 4A, the flip-flop FF2 is also changed to the scan flip-flop SFF2 as illustrated in FIG. 3. In Step S3, the wiring is connected as illustrated in FIG. 3 such that the scan flip-flop SFF2 acts as the flip-flop. Because other pieces of processing are similar to those of the first embodiment, the description will not be repeated.

### Third Embodiment

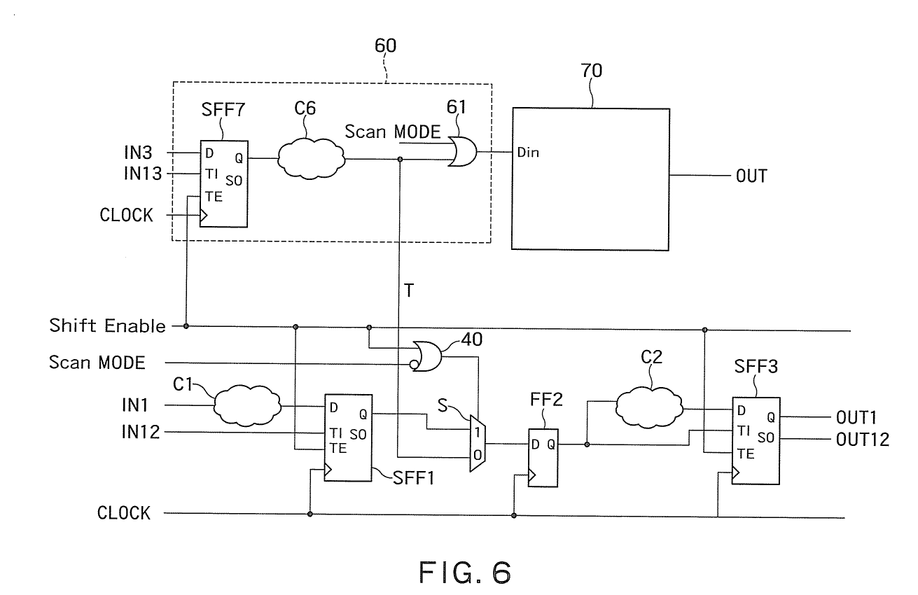

A third embodiment of the invention will be described with reference to FIG. 6. In the third embodiment, the combination circuit that is not originally incorporated in the scan test circuit is incorporated in the scan test circuit.

In some circuits, it is necessary to fix the control signal to a constant value in performing the scan test. A power supply circuit (control target circuit) that is controlled based on the output data of the preceding flip-flop can be cited as an example of the above circuit. At this point, during the scan test, the control signal fed into the power supply circuit is fixed to a constant value independently of the output data of the preceding flip-flop. In the third embodiment, the scan test circuit including the above power supply circuit will be described by way of example.

FIG. 6 is a circuit diagram of a scan test circuit of the third embodiment. A power supply control circuit 60 includes a scan flip-flop SFF7, a combination circuit C6, and a logic circuit 61. Pieces of data IN3 and IN13 are fed from the preceding circuit (not illustrated) into the input terminals D and TI of the scan flip-flop SFF7. The output data is fed into the combination circuit C6 from the output terminal Q of the scan flip-flop SFF7. The output data T (observation data) of the combination circuit C6 and the scan mode signal are fed into the logic circuit 61. At this point, the logic circuit 61 is an OR circuit. Predetermined data is fed into the scan flip-flop SFF7 through a preceding circuit and the like by the shift operation in the scan test. The output data of the logic circuit 61 is fed into an input terminal Din of a power supply circuit 70.

The power supply circuit 70 is turned on to output a output voltage OUT when the high data is fed into the input terminal Din, and is turned off when the low data is fed into the input terminal Din.

Occasionally, the output voltage OUT is also used in another circuit (not illustrated) in the scan test. Therefore, it is necessary that the power supply circuit 70 outputs the output voltage OUT during the scan test. Therefore, the data fed into the input terminal Din is fixed high by the logic circuit 61 when the scan mode signal is set high (that is, in the shift operation and the capture operation).

Output data T is fed into the input terminal “0” of the selector S that is inserted and connected between the scan flip-flop SFF1 and the flip-flop FF2. Because other circuit configurations are identical to those of the scan test circuit of FIG. 4, the same component is designated by the same numeral, and the description will not be repeated.

In the configuration of FIG. 6, the output data T is stored in the flip-flop FF2 by the capture operation in the scan test, is output from the external output terminal through the scan flip-flop SFF3 and the like by the shift operation, and can be observed.

As described above, according to the third embodiment, the output data T of the combination circuit C6 that functions as the observation target circuit is fed into the subsequent flip-flop FF2 in the shift register SR, so that the output data T can be observed without adding newly the flip-flop dedicated to the scan test. Accordingly, the observability can be improved to enhance the fault coverage while the increase in area is prevented. Because the number of stages of the flip-flops in the scan chain is not changed, the time necessary for the shift operation is not lengthened. Accordingly, the increase in test time is prevented.

In addition, in the third embodiment, the OR circuit is used as the logic circuit 61 by way of example. Alternatively, other circuits may be used as the logic circuit 61. For example, when a NOR circuit is used as the logic circuit 61, the data fed into the input terminal Din of the power supply circuit 70 is fixed low during the scan test, and the operation of the power supply circuit 70 can be stopped. This can be applied to the following case. Because all the flip-flops that function as targets of the scan test are operated in performing the scan test, a current consumption in the scan test easily becomes larger than that in the normal operation. Therefore, in order to reduce a current load on an external test device and the like, the operation of the scan nontarget block such as an analog circuit (the power supply circuit 70 in this case) that consumes the current is stopped using the configuration in which the NOR circuit is used as the logic circuit 61.

In addition, the method for changing the circuit to the scan test circuit of FIG. 6 differs from that of the first embodiment in the following point. That is, in Step S4 of FIG. 4A, the combination circuit C6 that is not included in the targets of the scan test is searched as the observation target circuit, and the output terminal of the searched combination circuit C6 is connected to the selector S. Because other pieces of processing are similar to those of the first embodiment, the description will not be repeated.

The embodiments of the invention are described above in detail. However, the specific configuration is not limited to the embodiments, but various modifications can be made without departing from the scope of the invention.

For example, the shift register SR may be formed by connecting the plural flip-flops in series. The shift registers SR may be provided at plural points in the scan test circuit. In such cases, each selector is provided in the input of each flip-flop, and the data of each of the plural observation target circuits is fed into each selector, which allows the plural pieces of data to be observed. Accordingly, the observability can be more enhanced while the increase in area is prevented.

The output data T of the combination circuit C6 in the third embodiment may be fed into the input terminal “0” of the selector S in the second embodiment.

The logical value of the shift enable signal, the scan mode signal, the observation target selection signal, and the switching signal to the control terminal of the selector S is not limited to the above-described logical value. That is, any logical value may be used, as long as the signal of the scan flip-flop SFF1 can be fed into the flip-flop FF2 in the normal operation and the shift operation, and as long as observation data can be fed into the flip-flop FF2 in the capture operation. In addition, another signal may be used instead of the shift enable signal.

In the second and third embodiments, an observation target selection signal may be fed into the OR circuit 40 instead of the scan mode signal.

1. A scan test circuit that performs a normal operation, a shift operation, and a capture operation based on a control signal, the scan test circuit comprising:
a plurality of combination circuits;
a plurality of scan flip-flops, the plurality of scan flip-flops and the plurality of combination circuits being alternately connected in series;
a flip-flop connected between the scan flip-flop and the subsequent combination circuit not through the combination circuit; and
a selector switched between a first mode and a second mode by a switching signal, the selector feeding observation data of a predetermined observation target circuit into the flip-flop in the first mode, the selector feeding output data of a preceding circuit of the flip-flop into the flip-flop in the second mode, the selector being able to be switched to the first mode during the capture operation in a scan test, the selector being able to be switched to the second mode during the normal operation and the shift operation in the scan test.

2. The scan test circuit according to claim 1, wherein the selector is switched to the first mode during the capture operation when a stuck-at fault test is performed as the scan test, and
the selector is switched to the second mode during the capture operation when a delay fault test is performed as the scan test.

3. The scan test circuit according to claim 1, wherein each of the scan flip-flops is configured to store output data of the preceding combination circuit and output the stored output data according to a clock during both the normal operation and the capture operation, and to store output data of the preceding scan flip-flop or preceding flip-flop and output the stored output data according to the clock during the shift operation, and
the flip-flop is configured to store output data of the preceding circuit and output the stored output data according to the clock during the second mode, and to store the observation data and output the stored observation data according to the clock during the first mode.

4. The scan test circuit according to claim 1, wherein the observation target circuit is one of the plurality of combination circuits.

5. The scan test circuit according to claim 1, wherein the observation target circuit is a combination circuit having the longest delay time in the plurality of combination circuits.

6. The scan test circuit according to claim 5, wherein the observation data is data at a midpoint of the combination circuit having the longest delay time.

7. The scan test circuit according to claim 1, comprising a logic circuit into which output data of the observation target circuit is fed,
wherein output data of the logic circuit is fixed to a constant value in the scan test,
the output data of the logic circuit is supplied to a predetermined control target circuit, and
the control target circuit is controlled in an on state or an off state by the output data of the logic circuit.

8. The scan test circuit according to claim 7, wherein the control target circuit is controlled in the on state in the scan test.

9. The scan test circuit according to claim 7, wherein the control target circuit is controlled in the off state in the scan test.

10. The scan test circuit according to claim 7, wherein the control target circuit is a power supply circuit.

11. The scan test circuit according to claim 1, wherein the flip-flop is formed using the scan flip-flop that acts as a flip-flop.

12. The scan test circuit according to claim 11, wherein each of the scan flip-flops comprises a first input terminal, a second input terminal, a control terminal, and an output terminal,
each of the scan flip-flops is configured to store a signal from one of the first input terminal and the second input terminal, and output the stored signal according to a clock, one of the first input terminal and the second input terminal being determined by a logical value of the control terminal, and
the flip-flop is formed using the scan flip-flop in which the logical value of the control terminal is set to a constant value.

13. A method for changing a predetermined circuit to a scan test circuit, the predetermined circuit comprising a plurality of combination circuits, a plurality of first flip-flops, the plurality of first flip-flops and the plurality of combination circuits being alternately connected in series, and a second flip-flop connected between the first flip-flop and the subsequent combination circuit not through the combination circuit, the method comprising:
replacing the plurality of first flip-flops with a plurality of scan flip-flops, respectively;
after replacing, changing wiring such that a scan test is able to be performed; and
after changing the wiring, connecting a selector switched between a first mode and a second mode by a switching signal such that observation data of a predetermined observation target circuit is fed into the second flip-flop in the first mode, and such that output data of a preceding circuit of the second flip-flop is fed into the second flip-flop in the second mode, the selector being able to be switched to the first mode during a capture operation in the scan test, the selector being able to be switched to the second mode during a normal operation and a shift operation in the scan test.

14. The method according to claim 13, wherein connecting the selector comprises:
searching a combination circuit as the observation target circuit, the combination circuit having the longest delay time in target circuits of the scan test; and
connecting a predetermined node in the searched combination circuit to an input terminal of the selector.

15. The method according to claim 13, wherein connecting the selector comprises:
searching a combination circuit as the observation target circuit, the combination circuit being not included in target circuits of the scan test; and
connecting an output terminal of the searched combination circuit to an input terminal of the selector.

16. A method for changing a predetermined circuit to a scan test circuit, the predetermined circuit comprising a plurality of combination circuits, a plurality of first flip-flops, the plurality of first flip-flops and the plurality of combination circuits being alternately connected in series, and a second flip-flop connected between the first flip-flop and the subsequent combination circuit not through the combination circuit, the method comprising:
replacing the plurality of first flip-flops with a plurality of scan flip-flops, respectively;
replacing the second flip-flop with a second scan flip-flop;
after replacing, providing wiring such that the second scan flip-flop acts as a flip-flop;
after providing the wiring, changing the wiring such that a scan test is able to be performed; and
after changing the wiring, connecting a selector switched between a first mode and a second mode by a switching signal such that observation data of a predetermined observation target circuit is fed into the second scan flip-flop in the first mode, and such that output data of a preceding circuit of the second scan flip-flop is fed into the second scan flip-flop in the second mode, the selector being able to be switched to the first mode during a capture operation in the scan test, the selector being able to be switched to the second mode during a normal operation and a shift operation in the scan test.

17. The method according to claim 16, wherein connecting the selector comprises:
searching a combination circuit as the observation target circuit, the combination circuit having the longest delay time in target circuits of the scan test; and
connecting a predetermined node in the searched combination circuit to an input terminal of the selector.

18. The method according to claim 16, wherein connecting the selector comprises:
searching a combination circuit as the observation target circuit, the combination circuit being not included in target circuits of the scan test; and
connecting an output terminal of the searched combination circuit to an input terminal of the selector.
